(19) United States
(12) Patent Application Publication
(10) Pub. No.: US 2026/0271639 A1
(43) Pub. Date: Sep. 10, 2026

(54) TANTALUM CARBIDE COATING MATERIAL AND COMPOUND SEMICONDUCTOR GROWTH DEVICE

(71) Applicant: SHIN-ETSU CHEMICAL CO., LTD., Tokyo (JP)

(72) Inventors: Naoya MIYAJIMA, Annaka-shi (JP); Akihiro HIRATE, Takasaki-shi (JP); Waichi YAMAMURA, Annaka-shi (JP)

(73) Assignee: SHIN-ETSU CHEMICAL CO., LTD., Tokyo (JP)

(21) Appl. No.: 19/165,814

(22) PCT Filed: Mar. 5, 2024
(86) PCT No.: PCT/JP2024/008317

§ 371 Date: Sep. 16, 2025

(30) Foreign Application Priority Data
Mar. 30, 2023 (JP) 2023-055682

(51) Int. Cl. H10P 14/69; C04B 41/87; C23C 16/32; H10P 14/24

(52) U.S. Cl. CPC H10P 14/691; C04B 41/87; C23C 16/32; H10P 14/24

(57) ABSTRACT

A tantalum carbide-coated material including a substrate and a tantalum carbide coating film covering at least part of the substrate, in which the number of crack intersections per unit area on a surface of the tantalum carbide coating film is 25 or less per cm². A compound semiconductor growth apparatus according to the present invention uses the tantalum carbide-coated material. A tantalum carbide-coated material in which a tantalum carbide coating film is less likely to delaminate in a high-temperature corrosive environment; and a compound semiconductor growth apparatus using the tantalum carbide-coated material.

### TECHNICAL FIELD

The present invention relates to a tantalum carbide-coated material in which the surface of a substrate is covered with a tantalum carbide coating film; and a compound semiconductor growth apparatus using the tantalum carbide-coated material.

### BACKGROUND ART

Tantalum carbide, niobium carbide, zirconium carbide, hafnium carbide, tungsten carbide, and other carbides have high melting points and excellent chemical stability, strength, toughness, and corrosion resistance. For this reason, carbide coating of carbon substrates can improve the properties of the carbon substrates, such as heat resistance, chemical stability, strength, toughness, and corrosion resistance. Carbide-coated carbon materials, in which the surface of a carbon substrate is coated with a carbide film, in particular tantalum carbide-coated carbon materials, are used as the components of a compound semiconductor growth apparatus for compound semiconductors such as silicon carbide (SiC), gallium nitride (GaN), and aluminum nitride (AlN). For example, to obtain higher-quality crystals in an SiC single-crystal production apparatus, PTL 1 discloses using a crucible in which the inner surface of a graphite substrate is coated with tantalum carbide. PTL 2 discloses using, as a guide component of an SiC single-crystal production apparatus, a guide component having an inner wall coated with tantalum carbide.

### CITATION LIST

### Patent Literature

PTL 1: JP 2019-99453 A
PTL 2: JP 2019-108611 A

### SUMMARY OF INVENTION

### Technical Problem

However, compound semiconductors are facing the problem of a higher production cost than that for conventional Si semiconductors. To further reduce this production cost, there is a need for highly heat-resistant components having a further enhanced corrosion resistance. For example, the environment for SiC single-crystal production is a harsh environment where the temperature exceeds 2,000° C. Even under such a high-temperature corrosive environment, tantalum carbide-coated materials are required to be free from delamination of the tantalum carbide coating film and to be highly durable.

Therefore, an object of the present invention is to reduce the likelihood of a tantalum carbide coating film delaminating in a high-temperature corrosive environment.

### Solution to Problem

The present inventors conducted intensive and extensive investigations, and finally found that when the surface of the tantalum carbide coating film has fewer crack intersections, the tantalum carbide coating film is less likely to delaminate after use in SiC single-crystal production. On the basis of this finding, the present inventors have completed the present invention. The scope of the present invention is as follows.
[1] A tantalum carbide-coated material including a substrate and a tantalum carbide coating film covering at least part of the substrate, in which the number of crack intersections per unit area on a surface of the tantalum carbide coating film is 25 or less per cm².
[2] The tantalum carbide-coated material according to the above [1] or [2], in which the average width of roughness profile elements Rsm of the surface of the tantalum carbide coating film is 10 μm or less.
[3] The tantalum carbide-coated material according to the above [1] or [2], in which the average width of roughness profile elements Rsm of an interface between the substrate and the tantalum carbide coating film is 0.1 mm or more and 5.0 mm or less.
[4] The tantalum carbide-coated material according to any one of the above [1] to [3], in which the substrate is a carbon substrate containing carbon as a main component.
[5] The tantalum carbide-coated material according to any one of the above [1] to [4], in which the adhesion strength between the tantalum carbide coating film and the substrate is 5 MPa or more.
[6] The tantalum carbide-coated material according to any one of the above [1] to [5], in which the substrate has a linear thermal expansion coefficient of 3.5×10⁻⁶/° C. or more and 7.5×10⁻⁶/C or less.
[7] A compound semiconductor growth apparatus using the tantalum carbide-coated material according to any one of the above [1] to [6].

### Advantageous Effects of Invention

The present invention can provide a tantalum carbide-coated material in which a tantalum carbide coating film is less likely to delaminate in a high-temperature corrosive environment; and a compound semiconductor growth apparatus using the tantalum carbide-coated material.

### BRIEF DESCRIPTION OF DRAWINGS

FIG. 1 is a schematic cross-sectional view illustrating a tantalum carbide-coated material according to an embodiment of the present invention.

FIG. 2 is a schematic view of a hot-wall low-pressure CVD apparatus.

FIG. 3(a) is an image diagram of a film surface on which there are two cracks per unit area and these cracks have an intersection, and FIG. 3(b) is an image diagram of the cross section a-a′ of FIG. 3(a).

FIG. 4(a) is an image diagram of a film surface on which there are two cracks per unit area and these cracks have no intersection, and FIG. 4(b) is an image diagram of the cross section b-b′ of FIG. 4(a).

FIG. 5 is a scanning electron microscope (SEM) image of the surface of the tantalum carbide-coated carbon material after use in SiC single-crystal production.

FIG. 6 is a diagram illustrating a method for measuring the adhesion strength between the tantalum carbide coating film and the substrate.

### DESCRIPTION OF EMBODIMENTS

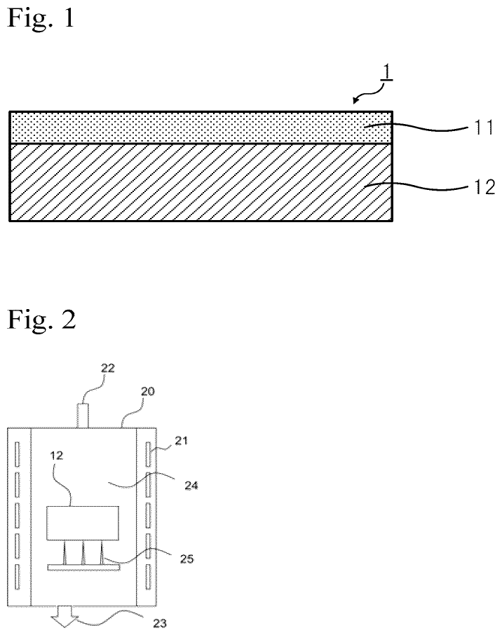

The tantalum carbide-coated material according to one embodiment of the present invention will be described with reference to FIG. 1.

### Tantalum Carbide-Coated Material

A tantalum carbide-coated material 1 according to one embodiment of the present invention includes a substrate 12 and a tantalum carbide coating film 11 covering at least part of the substrate 12. The number of crack intersections per unit area on the surface of the tantalum carbide coating film 11 is 25 or less per cm².

### Substrate

The substrate 12 in the tantalum carbide-coated material 1 according to one embodiment of the present invention may be any type of substrate suitable for its intended use. Examples of the substrate 12 include carbon substrates containing carbon as a main component and using carbon materials such as isotropic graphite, extruded graphite, pyrolytic graphite, and carbon fiber reinforced carbon matrix composites (C/C composites), and high-melting-point metal substrates using high-melting-point metal materials such as tantalum. Among these substrates, a carbon substrate containing carbon as a main component is preferable as the substrate 12 in the tantalum carbide-coated material 1 according to one embodiment of the present invention. The shape and properties of the substrate are not particularly limited, and the substrate can be processed into any shape according to the application and the like.

### Linear Thermal Expansion Coefficient

The linear thermal expansion coefficient of the substrate 12 is preferably 3.5×10⁻⁶/° C. or more and 7.5×10⁻⁶/° C. or less. When the linear thermal expansion coefficient of the carbon substrate 12 is 3.5×10⁻⁶/° C. or more and 7.5×10⁻⁶/° C. or less, cracking on the surface of the tantalum carbide-coated material 1 can be further mitigated. In this view, the linear thermal expansion coefficient of the carbon substrate 12 is more preferably 3.5×10⁻⁶/° C. or more and 7.5×10⁻⁶/° C. or less, and even more preferably 5.6×10⁻⁶/° C. or more and 7.5×10⁻⁶/C or less. The linear thermal expansion coefficient of the tantalum carbide coating film 11 is about 6.3×10⁻⁶/° C. The linear thermal expansion coefficient of the substrate can be measured in accordance with JIS R 1618.

### Tantalum Carbide Coating Film

The tantalum carbide coating film 11 contains tantalum carbide as a main component and covers the substrate 12. The tantalum carbide coating film 11 may cover part of the substrate 12 or the whole substrate 12.

### Number of Crack Intersections

The number of crack intersections per unit area on the surface of the tantalum carbide coating film 11 is 25 or less per cm². When the number of crack intersections on the surface of the tantalum carbide coating film 11 per unit area is more than 25 per cm², exposure to a high-temperature corrosive environment causes greater damage to the substrate 12 due to the cracks on the surface of the tantalum carbide coating 11, and the tantalum carbide coating film 11 may delaminate. In this view, the number of crack intersections per unit area on the surface of the tantalum carbide coating film 11 is preferably 24.9 or less per cm², more preferably 23 or less per cm², still more preferably 21.3 or less per cm², even more preferably 13.4 or less per cm², and particularly preferably 6.8 or less per cm². The lower limit in the range of the number of crack intersections per unit area on the surface of the tantalum carbide coating film 11 is 0 per cm². The number of crack intersections per unit area on the surface of the tantalum carbide coating film 11 can be adjusted by varying the average width of roughness profile elements Rsm of the substrate 12 and the linear thermal expansion coefficient of the substrate 12.

The reason why fewer crack intersections per unit area on the surface of the tantalum carbide coating film 11 result in less likelihood of the tantalum carbide coating film 11 delaminating is explained below. The explanation below does not limit the tantalum carbide-coated material according to the present invention.

It is known that when the tantalum carbide-coated material 1 having cracks on the surface of the tantalum carbide coating film 11 is exposed to a high-temperature corrosive environment at 2,000° C. or more, damage to the substrate 12 develops centering on individual cracks (for example, see JP 2022-87846 A). As the damaged part of the substrate 12 enlarges, the substrate 12 can no longer support the tantalum carbide coating film 11, resulting in the delamination of the tantalum carbide coating film 11. In the vicinity of a crack intersection, greater damage occurs to the substrate 12 due to the presence of two cracks, so that the damage to the substrate 12 rapidly enlarges. As a result, the tantalum carbide coating film 11 is even more likely to delaminate. Once the tantalum carbide coating film 11 has delaminated, damage progresses in the part of the substrate 12 from which the tantalum carbide coating film 11 is delaminated. As a result, the delamination of the tantalum carbide coating film 11 further progresses. In this way, the tantalum carbide-coated material falls into a vicious cycle of the delamination of the tantalum carbide coating film 11 and the damage to the substrate 12.

Therefore, when the surface of the tantalum carbide coating film 11 has fewer crack intersections per unit area, the acceleration of substrate damage due to the two cracks is suppressed, and thus the tantalum carbide coating film 11 is less likely to delaminate.

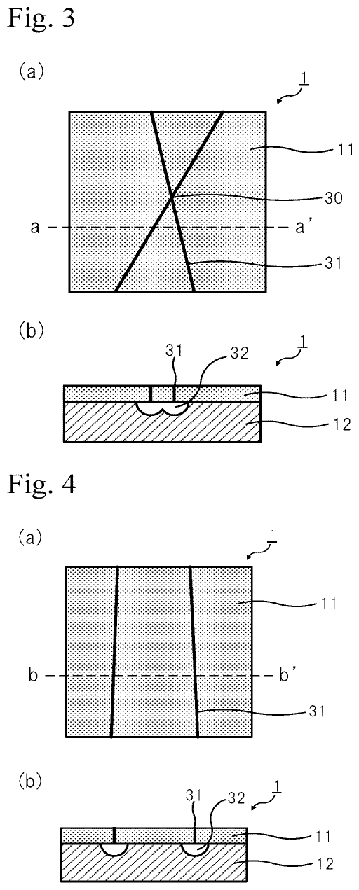

Now, we consider two cases where the surface of the tantalum carbide coating film 11 has two cracks per unit area: one case where the two cracks have an intersection (see FIG. 3) and the other case where the two cracks have no intersection (see FIG. 4). When the respective tantalum carbide-coated materials 1 are exposed to a high-temperature corrosive environment, damage to the substrate 12 develops from the vicinity of cracks 31, and in the case where the cracks 31 have an intersection 30, a damage 32 is expected to be larger in size in the vicinity of the intersection 30 than in the case where the cracks 31 have no intersection (see FIGS. 3(b) and 4(b)). As such, the tantalum carbide coating film is more likely to delaminate in the vicinity of the crack intersection 30 than in the vicinity of an ordinary crack 31.

FIG. 5 is an image obtained by scanning electron microscope (SEM) observation of the surface of the tantalum carbide-coated carbon material after actual use in an SiC single-crystal growth environment, and this figure confirms that the tantalum carbide coating film is delaminated at around the crack intersection. Therefore, when the surface of the tantalum carbide coating film 11 has fewer crack intersections per unit area, i.e., the number of crack intersections per unit area on the surface of the tantalum carbide coating film 11 is 25 or less per cm², the tantalum carbide coating film is less likely to delaminate when the tantalum carbide-coated material is exposed to a high-temperature corrosive environment.

The number of crack intersections per unit area on the surface of the tantalum carbide coating film 11 can be measured as follows.

Since the cracks present in the tantalum carbide-coated material are of a size not visible to the naked eye, the number of crack intersections per unit area on the surface of the tantalum carbide coating film 11 is measured by either or both of the following two methods.

### (1) Measurement Using a Scanning Electron Microscope (SEM)

A sample is processed to a size observable with SEM before its surface is observed. In this case, about 17 images need to be acquired to observe a 1-cm² area, because the maximum information obtained from a single image is about 6 mm² (=2 mm×3 mm). In addition, about 17 images need to be acquired at a sufficiently distant and separate site to eliminate a bias based on localized observation. This procedure is repeated 10 times to obtain a total of 170 images or more. In the total of 170 images or more, the number of crack intersections is counted. The number of crack intersections is divided by the area of the observed sites shown in the total of 170 acquired images or more, and the resulting value is the number of crack intersections per unit area (number/cm²) on the surface of the tantalum carbide coating film 11.

### (2) Measurement Using a Flaw Detection Agent

Some shapes of samples require processing for SEM observation, and this processing itself may cause cracks on the surface of the tantalum carbide coating film. To exclude this possibility, a flaw detection agent capable of detecting micrometer-sized cracks may be used to visualize cracks, and the number of crack intersections per cm² may be measured with the naked eye or an optical microscope.

### Average Width of Roughness Profile Elements Rsm

The average width of roughness profile elements Rsm of the surface of the tantalum carbide coating film 11 is preferably 10 μm or less. When the average width of roughness profile elements Rsm of the surface of the tantalum carbide coating film 11 is 10 μm or less, the adhesion of atmospheric dust and the like on the surface of the tantalum carbide coating film 11 can be mitigated. In this view, the average width of roughness profile elements Rsm of the surface of the tantalum carbide coating film 11 is more preferably 9.8 μm or less, and even more preferably 6.5 μm or less. The lower limit in the range of the average width of roughness profile elements Rsm of the surface of the tantalum carbide coating film 11 is not particularly specified and is usually 1.1 μm.

The average width of roughness profile elements Rsm of the interface between the substrate 12 and the tantalum carbide coating film 11 is preferably 0.1 mm or more and 5.0 mm or less. When the average width of roughness profile elements Rsm of the interface between the substrate 12 and the tantalum carbide coating film 11 is 0.1 mm or more and 5.0 mm or less, the adhesion strength between the substrate 12 and the tantalum carbide coating film 11 can be further enhanced. In addition, when the average width of roughness profile elements Rsm of the interface between the substrate 12 and the tantalum carbide coating film 11 is 0.1 mm or more and 5.0 mm or less, the number of crack intersections per unit area on the surface of the tantalum carbide coating film 11 can be further reduced. In this view, the average width of roughness profile elements Rsm of the interface between the substrate 12 and the tantalum carbide coating film 11 is more preferably 0.5 mm or more and 5.0 mm or less, still more preferably 1.0 mm or more and 5.0 mm or less, and even more preferably 2.0 mm or more and 5.0 mm or less. The average width of roughness profile elements Rsm of the interface between the substrate 12 and the tantalum carbide coating film 11 is the same value as the average width of roughness profile elements Rsm of the surface of the substrate 12. Therefore, controlling the average width of roughness profile elements Rsm of the surface of the substrate 12 within the above range ensures that the average width of roughness profile elements Rsm of the interface between the substrate 12 and the tantalum carbide coating film 11 is also within the above range. The average width of roughness profile elements Rsm of the surface of the substrate 12 may be attributed to an intentionally produced pattern or to cutting tool marks made during machining.

The average width of roughness profile elements Rsm can be measured with a commercially available surface roughness tester or using microscopic images of a fracture cross section, and is the average width of roughness profile elements as specified in JIS B 0601:2013 and ISO 4287:1997. The average width of roughness profile elements RSm is represented by the formula below, using a distance xi from the i-th peak to the i+1-th peak and the number m of intervals between the peaks in the cross-sectional profile.

$$Rsm = ( 1 / m ) \times {\sum }_{Xi} ( i = 1 to m )$$

The minimum height required for identifying peaks is 10% of the average height of the cross-sectional profile Rz.

When the average width of roughness profile elements Rsm is a larger value, the roughness formed can be said to have a longer periodic interval, and when the average width of roughness profile elements Rsm is a smaller value, the roughness formed can be said to have a shorter periodic interval.

The adhesion strength between the tantalum carbide coating film 11 and the substrate 12 is preferably 5 MPa or more. When the adhesion strength between the tantalum carbide coating film 11 and the substrate 12 is 5 MPa or more, the tantalum carbide coating film is further less likely to delaminate in a high-temperature corrosive environment. In this view, the adhesion strength between the tantalum carbide coating film 11 and the substrate 12 is more preferably 5.1 MPa or more, and even more preferably 6.5 MPa or more. The upper limit in the range of the adhesion strength between the tantalum carbide coating film 11 and the substrate 12 is not particularly specified and is usually 18.5 MPa.

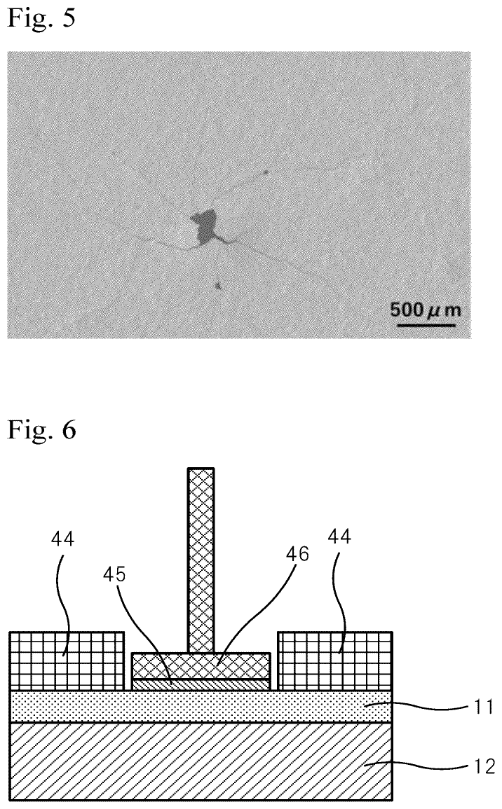

The adhesion strength between the tantalum carbide coating film 11 and the substrate 12 was measured, for example, using a thin film adhesion strength tester (manufactured by Quad Group Inc., trade name “Romulus”). As shown in FIG. 6, a tantalum carbide coating film 11 and a stud pin 46 were bonded together with an adhesive 45, the tantalum carbide coating film was firmly held with a holding jig 44, and the stud pin 46 was pulled. The stress at which the tantalum carbide coating film 41 was delaminated was measured. Five measurements are taken, and the average value calculated from the five measurements is used as the adhesion strength.

### Method for Producing the Tantalum Carbide-Coated Material

The tantalum carbide-coated material according to one embodiment of the present invention can be produced by forming a tantalum carbide coating film on the surface of a substrate. For example, the tantalum carbide coating film can be formed on the surface of the substrate by chemical vapor deposition (CVD), sintering, carbonization, or the like. Among these techniques, CVD is a preferable technique for forming the tantalum carbide layer because CVD enables the formation of a uniform and dense film.

Furthermore, CVD includes thermal CVD, photo CVD, and plasma-enhanced CVD. The tantalum carbide coating film can be formed by, for example, thermal CVD. Thermal CVD has some advantages such as using an apparatus with a relatively simple configuration and not causing plasma-induced damage. The formation of the tantalum carbide coating film by thermal CVD can be performed, for example, using a hot-wall low-pressure CVD apparatus 20 as shown in FIG. 2. In the hot-wall low-pressure CVD apparatus 20, a substrate 12 is supported by a support means 25 in a reaction chamber 24 provided with a heater 21, a source supply unit 22, an exhaust unit 23, and others.

The method for producing the tantalum carbide-coated material according to one embodiment of the present invention will be described with reference to FIGS. 1 and 2.

First, a substrate 12 is placed in a reaction chamber 24 of a hot-wall low-pressure CVD apparatus 20. The substrate 12 is supported by a support means 25 having support parts each having a sharply pointed tip.

Next, a heater 21 is heated. For example, the heater 21 is heated under the conditions of low pressure at a temperature of 1,000 to 2,500° C.

Then, a tantalum carbide coating film is formed on the surface of the substrate 12. As source gases, a carbon atom-containing compound gas such as methane (CH₄) and a tantalum halide gas such as tantalum pentachloride (TaCl₅) are supplied into the reaction chamber 24 from a source supply unit 22. Then, the source gases supplied from the source supply unit 22 are subjected to a thermal CVD reaction at a high temperature of 1,000 to 2,500° C. under low pressure to form a tantalum carbide coating film on the surface of the substrate 12.

The tantalum carbide-coated material according to one embodiment of the present invention is one example of the tantalum carbide-coated material according to the present invention, and thus, the tantalum carbide-coated material according to one embodiment of the present invention does not limit the tantalum carbide-coated material according to the present invention.

### Compound Semiconductor Growth Apparatus

The compound semiconductor growth apparatus according to the present invention uses the tantalum carbide-coated material according to the present invention. The tantalum carbide-coated material according to the present invention is used as the component of a compound semiconductor growth apparatus for compound semiconductors such as silicon carbide (SiC), gallium nitride (GaN), and aluminum nitride (AlN).

### EXAMPLES

Hereinafter, examples are provided to describe the present invention in more detail, but the present invention is not limited thereto.

Tantalum carbide-coated carbon materials of Examples 1 to 17 and Comparative Examples 1 to 6 were produced as follows.

### Example 1

Two workpieces of an isotropic carbon material having a linear thermal expansion coefficient of 3.5×10⁻⁶/° C. in which the average width of roughness profile elements Rsm of the surface was 4.3 mm were prepared as a substrate 12. The linear thermal expansion coefficient was measured with a thermomechanical analyzer (manufactured by Hitachi High-Tech Science Corporation, trade name “TMA7300”) using a sample of the same type of carbon material. The average width of roughness profile elements Rsm of the surface of the substrate 12 was measured with a surface roughness tester (manufactured by Mitutoyo Corporation, trade name, “SJ201”).

Next, the substrate 12 was placed in a reaction chamber of a hot-wall low-pressure CVD apparatus 20 shown in FIG. 2. The substrate 12 was supported by a support means 25 having three support parts each having a sharply pointed tip.

Next, the reaction chamber 24 was heated at a temperature of 1,500° C., TaCl₅ gas, CH₄ gas, and Ar gas were mixed, and the resulting mixed gas was supplied into the reaction chamber 24 to form a tantalum carbide coating film on the surface of the carbon substrate 12. Thus, a tantalum carbide-coated carbon material of Example 1 was produced. The flow rates of CH₄ gas and carrier gas (Ar gas) were controlled to 1.0 SLM and 1.0 SLM, respectively, with a mass flow controller.

Among the two tantalum carbide-coated carbon material products, one was used for various measurements described below, and the other was used for SiC single-crystal production, in which the number of cycles of use before the delamination of the tantalum carbide coating film could be confirmed with the naked eye was counted.

For one tantalum carbide-coated carbon material product, the number of crack intersections per unit area on the surface of the tantalum carbide coating film, the average width of roughness profile elements Rsm of the surface of the tantalum carbide coating film, and the adhesion strength between the tantalum carbide coating film and the substrate were measured. The method for measuring the number of crack intersections per unit area on the surface of the tantalum carbide coating film was as described above and an SEM (manufactured by Keyence Corporation, trade name “VE8800”) and a flaw detection agent (manufactured by Ichinen chemicals Co., Ltd., Micro-Check cleaner, Micro-Check penetrating solution, and Micro-Check development solution) were used. The surface roughness of the tantalum carbide coating film was measured with a surface roughness tester (manufactured by Mitutoyo Corporation, trade name, “SJ201”). The adhesion strength between the substrate 12 and the tantalum carbide coating film 11 was measured with a thin film adhesion strength tester (manufactured by Quad Group Inc., trade name “Romulus”).

### Example 2

Two workpieces of an isotropic carbon material having a thermal expansion coefficient of 4.2×10⁻⁶/° C. in which the average width of roughness profile elements Rsm of the surface was 4.2 mm were prepared as the substrate 12. These workpieces were subjected to the same procedures as in Example 1.

### Example 3

Two workpieces of an isotropic carbon material having a thermal expansion coefficient of 4.5×10⁻⁶/° C. in which the average width of roughness profile elements Rsm of the surface was 4.6 mm were prepared as the substrate 12. These workpieces were subjected to the same procedures as in Example 1.

### Example 4

Two workpieces of an isotropic carbon material having a thermal expansion coefficient of 5.1×10⁻⁶/° C. in which the average width of roughness profile elements Rsm of the surface was 4.1 mm were prepared as the substrate 12. These workpieces were subjected to the same procedures as in Example 1.

### Example 5

Two workpieces of an isotropic carbon material having a thermal expansion coefficient of 5.6×10⁻⁶/° C. in which the average width of roughness profile elements Rsm of the surface was 4.5 mm were prepared as the substrate 12. These workpieces were subjected to the same procedures as in Example 1.

### Example 6

Two workpieces of an isotropic carbon material having a thermal expansion coefficient of 6.0×10⁻⁶/° C. in which the average width of roughness profile elements Rsm of the surface was 4.4 mm were prepared as the substrate 12. These workpieces were subjected to the same procedures as in Example 1.

### Example 7

Two workpieces of an isotropic carbon material having a thermal expansion coefficient of 6.4×10⁻⁶/° C. in which the average width of roughness profile elements Rsm of the surface was 4.4 mm were prepared as the substrate 12. These workpieces were subjected to the same procedures as in Example 1.

### Example 8

Two workpieces of an isotropic carbon material having a thermal expansion coefficient of 6.9×10⁻⁶/° C. in which the average width of roughness profile elements Rsm of the surface was 4.3 mm were prepared as the substrate 12. These workpieces were subjected to the same procedures as in Example 1.

### Example 9

Two workpieces of an isotropic carbon material having a thermal expansion coefficient of 7.5×10⁻⁶/° C. in which the average width of roughness profile elements Rsm of the surface was 4.2 mm were prepared as the substrate 12. These workpieces were subjected to the same procedures as in Example 1.

### Example 10

Two workpieces of an isotropic carbon material having a linear thermal expansion coefficient of 4.2×10⁻⁶/° C. in which the average width of roughness profile elements Rsm of the surface was 0.1 mm were prepared as the substrate 12. These workpieces were subjected to the same procedures as in Example 1.

### Example 11

Two workpieces of an isotropic carbon material having a linear thermal expansion coefficient of 4.2×10⁻⁶/° C. in which the average width of roughness profile elements Rsm of the surface was 0.9 mm were prepared as the substrate 12. These workpieces were subjected to the same procedures as in Example 1.

### Example 12

Two workpieces of an isotropic carbon material having a linear thermal expansion coefficient of 4.2×10⁻⁶/° C. in which the average width of roughness profile elements Rsm of the surface was 2.1 mm were prepared as the substrate 12. These workpieces were subjected to the same procedures as in Example 1.

### Example 13

Two workpieces of an isotropic carbon material having a linear thermal expansion coefficient of 4.2×10⁻⁶/° C. in which the average width of roughness profile elements Rsm of the surface was 3.5 mm were prepared as the substrate 12. These workpieces were subjected to the same procedures as in Example 1.

### Example 14

Two workpieces of an isotropic carbon material having a linear thermal expansion coefficient of 4.2×10⁻⁶/° C. in which the average width of roughness profile elements Rsm of the surface was 5.0 mm were prepared as the substrate 12. These workpieces were subjected to the same procedures as in Example 1.

### Example 15

Two workpieces of an isotropic carbon material having a linear thermal expansion coefficient of 6.4×10⁻⁶/° C. in which the average width of roughness profile elements Rsm of the surface was 0.04 mm were prepared as the substrate 12. These workpieces were subjected to the same procedures as in Example 1.

### Example 16

Two workpieces of an isotropic carbon material having a linear thermal expansion coefficient of 6.9×10⁻⁶/° C. in which the average width of roughness profile elements Rsm of the surface was 0.02 mm were prepared as the substrate 12. These workpieces were subjected to the same procedures as in Example 1.

### Example 17

Two workpieces of an isotropic carbon material having a linear thermal expansion coefficient of 7.5×10⁻⁶/° C. in which the average width of roughness profile elements Rsm of the surface was 0.06 mm were prepared as the substrate 12. These workpieces were subjected to the same procedures as in Example 1.

### Comparative Example 1

Two workpieces of an isotropic carbon material having a linear thermal expansion coefficient of 3.5×10⁻⁶/° C. in which the average width of roughness profile elements Rsm of the surface was 0.04 mm were prepared as the substrate 12. These workpieces were subjected to the same procedures as in Example 1.

### Comparative Example 2

Two workpieces of an isotropic carbon material having a linear thermal expansion coefficient of 4.2×10⁻⁶/° C. in which the average width of roughness profile elements Rsm of the surface was 0.06 mm were prepared as the substrate 12. These workpieces were subjected to the same procedures as in Example 1.

### Comparative Example 3

Two workpieces of an isotropic carbon material having a linear thermal expansion coefficient of 4.5×10⁻⁶/° C. in which the average width of roughness profile elements Rsm of the surface was 0.03 mm were prepared as the substrate 12. These workpieces were subjected to the same procedures as in Example 1.

### Comparative Example 4

Two workpieces of an isotropic carbon material having a linear thermal expansion coefficient of 5.1×10⁻⁶/° C. in which the average width of roughness profile elements Rsm of the surface was 0.03 mm were prepared as the substrate 12. These workpieces were subjected to the same procedures as in Example 1.

### Comparative Example 5

Two workpieces of an isotropic carbon material having a linear thermal expansion coefficient of 5.6×10⁻⁶/° C. in which the average width of roughness profile elements Rsm of the surface was 0.06 mm were prepared as the substrate 12. These workpieces were subjected to the same procedures as in Example 1.

### Comparative Example 6

Two workpieces of an isotropic carbon material having a linear thermal expansion coefficient of 6.0×10⁻⁶/° C. in which the average width of roughness profile elements Rsm of the surface was 0.07 mm were prepared as the substrate 12. These workpieces were subjected to the same procedures as in Example 1.

The evaluation results of Examples 1 to 17 and Comparative Examples 1 to 6 are shown in Table 1.

TABLE 1

| | Thermal expansion | Rsm of surface | |
|---|---|---|---|
| | coefficient of | of substrate | Number of crack intersections |
| | substrate (×10⁻⁶ ° C.) | (mm) | per unit area (number/cm²) |
| Example 1 | 3.5 | 4.3 | 24.9 |
| Example 2 | 4.2 | 4.2 | 23.3 |
| Example 3 | 4.5 | 4.6 | 23.0 |
| Example 4 | 5.1 | 4.1 | 21.3 |
| Example 5 | 5.6 | 4.5 | 13.4 |
| Example 6 | 6.0 | 4.4 | 7.6 |
| Example 7 | 6.4 | 4.4 | 3.4 |
| Example 8 | 6.9 | 4.3 | 0.0 |
| Example 9 | 7.5 | 4.2 | 0.0 |
| Example 10 | 4.2 | 0.1 | 22.6 |
| Example 11 | 4.2 | 0.9 | 22.8 |
| Example 12 | 4.2 | 2.1 | 24.1 |
| Example 13 | 4.2 | 3.5 | 23.9 |
| Example 14 | 4.2 | 5.0 | 24.0 |
| Example 15 | 6.4 | 0.04 | 6.8 |
| Example 16 | 6.9 | 0.02 | 2.1 |
| Example 17 | 7.5 | 0.06 | 0.1 |
| Comparative | 3.5 | 0.04 | 123.4 |
| Example 1 | | | |
| Comparative | 4.2 | 0.06 | 100.1 |
| Example 2 | | | |
| Comparative | 4.5 | 0.03 | 96.2 |
| Example 3 | | | |
| Comparative | 5.1 | 0.03 | 89.6 |
| Example 4 | | | |
| Comparative | 5.6 | 0.06 | 58.2 |
| Example 5 | | | |
| Comparative | 6.0 | 0.07 | 26.3 |
| Example 6 | | | |

| | | | Number of cycles of use of |
|---|---|---|---|
| | Rsm of surface of | Adhesion | tantalum carbide-coated material |
| | tantalum carbide | strength | before delamination of tantalum |
| | coating film (μm) | (MPa) | carbide coating film (cycles) |
| Example 1 | 9.8 | 5.1 | 6 |
| Example 2 | 6.5 | 5.3 | 6 |
| Example 3 | 8.7 | 8.4 | 7 |
| Example 4 | 5.4 | 9.4 | 6 |
| Example 5 | 4.4 | 10.3 | 6 |
| Example 6 | 1.8 | 16.2 | 7 |
| Example 7 | 7.5 | 18.5 | 8 |
| Example 8 | 5.6 | 17.9 | 8 |
| Example 9 | 9.1 | 18.1 | 9 |
| Example 10 | 1.1 | 6.5 | 6 |
| Example 11 | 6.5 | 10.1 | 7 |
| Example 12 | 5.4 | 8.9 | 6 |
| Example 13 | 2.1 | 12.1 | 6 |
| Example 14 | 8.4 | 13.0 | 7 |
| Example 15 | 8.5 | 4.1 | 4 |
| Example 16 | 4.1 | 3.9 | 5 |
| Example 17 | 5.5 | 4.6 | 5 |
| Comparative | 3.6 | 4.8 | 1 |
| Example 1 | | | |
| Comparative | 2.7 | 4.3 | 1 |
| Example 2 | | | |
| Comparative | 6.4 | 3.6 | 2 |
| Example 3 | | | |
| Comparative | 2.7 | 4.6 | 2 |
| Example 4 | | | |
| Comparative | 5.6 | 4.9 | 2 |
| Example 5 | | | |
| Comparative | 1.1 | 4.6 | 3 |
| Example 6 | | | |

### Evaluation Results 1

Examples 1 to 17 and Comparative Examples 1 to 6 are compared. The cases where the number of crack intersections per unit area on the surface of the tantalum carbide coating film is 25 or less per cm² show a larger number of cycles of use of the tantalum carbide-coated material in the SiC single-crystal growth environment before the delamination of the tantalum carbide coating film than the cases where the number of crack intersections per unit area on the surface of the tantalum carbide coating film is more than 25 per cm².

These results demonstrate that when the number of crack intersections per unit area on the surface of the tantalum carbide coating film is 25 or less per cm², the tantalum carbide coating film is less likely to delaminate.

### Evaluation Results 2

In the comparison between Examples 1 to 14 versus Examples 15 to 17 and Comparative Examples 1 to 6, the cases where the average width of roughness profile elements Rsm of the surface of the tantalum carbide coating film is 10 μm or less show a larger number of cycles of use of the tantalum carbide-coated material in the SiC single-crystal growth environment before the delamination of the tantalum carbide coating film than the cases where the average width of roughness profile elements Rsm of the surface of the tantalum carbide coating film is more than 10 μm.

These results demonstrate that when the average width of roughness profile elements Rsm of the surface of the tantalum carbide coating film is 10 μm or less, the tantalum carbide coating film is less likely to delaminate.

### Evaluation Results 3

The comparison is made among Example 2, Examples 10 to 14, and Comparative Example 2, in each of which the substrate 12 used is a carbon material having a linear thermal expansion coefficient of 4.2×10⁻⁶/° C. The cases where the average width of roughness profile elements Rsm of the surface of the substrate is 0.1 mm or more and 5 mm or less (Example 2, Examples 10 to 14) show fewer crack intersections per unit area on the surface of the tantalum carbide coating film and a larger number of cycles of use before the delamination of the tantalum carbide coating film than the case where the average width of roughness profile elements Rsm of the surface of the substrate is 0.06 mm (Comparative Example 2).

These results indicate that the cases where the average width of roughness profile elements Rsm of the surface of the substrate is 0.1 mm or more and 5 mm or less are preferable.

### Evaluation Results 4

The comparisons are made between Example 1 and Comparative Example 1, between Example 2 and Comparative Example 2, between Example 3 and Comparative Example 3, between Example 4 and Comparative Example 4, between Example 5 and Comparative Example 5, between Example 6 and Comparative Example 6, between Example 7 and Example 15, between Example 8 and Example 16, and between Example 9 and Example 17. When the carbon materials used have the same linear thermal expansion coefficient, the cases where the average width of roughness profile elements Rsm of the surface of the carbon material is 0.1 mm or more and 5 mm or less show fewer crack intersections per unit area on the surface of the tantalum carbide coating film, a higher adhesion strength of 5 MPa or more, and a larger number of cycles of use before the delamination of the tantalum carbide coating film than the cases where the average width of roughness profile elements Rsm of the surface of the carbon material is less than 0.1 mm.

These results indicate that the cases where the average width of roughness profile elements Rsm of the surface of the substrate is 0.1 mm or more and 5 mm or less are preferable. That is, it can be understood that the cases where the average width of roughness profile elements Rsm of the interface between the substrate and the tantalum carbide coating film is 0.1 mm or more and 5.0 mm or less are preferable.

### REFERENCE SIGNS LIST

1 Tantalum carbide-coated material
11 Tantalum carbide coating film
12 Substrate
20 Hot-wall low-pressure CVD apparatus
21 Heater
22 Source supply unit
23 Exhaust unit
24 Reaction chamber
25 Support means
30 Crack intersection
31 Crack
32 Damage
44 Holding jig
45 Adhesive
46 Stud pin

1. A tantalum carbide-coated material, comprising:
a substrate; and
a tantalum carbide coating film covering at least part of the substrate,
wherein a number of crack intersections per unit area on a surface of the tantalum carbide coating film is 25 or less per cm².

2. The tantalum carbide-coated material according to claim 1, wherein an average width of roughness profile elements Rsm of the surface of the tantalum carbide coating film is 10 μm or less.

3. The tantalum carbide-coated material according to claim 1, wherein an average width of roughness profile elements Rsm of an interface between the substrate and the tantalum carbide coating film is from 0.1 mm to 5.0 mm.

4. The tantalum carbide-coated material according to claim 1, wherein the substrate is a carbon substrate comprising carbon as a main component.

5. The tantalum carbide-coated material according to claim 1, wherein an adhesion strength between the tantalum carbide coating film and the substrate is 5 MPa or more.

6. The tantalum carbide-coated material according to claim 1, wherein the substrate has a linear thermal expansion coefficient of from 3.5×10⁻⁶/° C. to 7.5×10⁻⁶/° C.

7. A compound semiconductor growth apparatus, comprising the tantalum carbide-coated material of claim 1.
